(19) United States
(12) Patent Application Publication
(10) Pub. No.: US 2024/0130138 A1
(43) Pub. Date: Apr. 18, 2024

(54) SEMICONDUCTOR MEMORY DEVICE AND ELECTRONIC SYSTEM INCLUDING THE SAME

(71) Applicant: SAMSUNG ELECTRONICS CO., LTD., SUWON-SI (KR)

(72) Inventors: Yukio HAYAKAWA, SUWON-SI (KR); Yong Seok KIM, SUWON-SI (KR); Bong Yong LEE, SUWON-SI (KR); Si Yeon CHO, SUWON-SI (KR)

(21) Appl. No.: 18/483,907

(22) Filed: Oct. 10, 2023

(30) Foreign Application Priority Data
Oct. 11, 2022 (KR) 10-2022-0129814
Mar. 23, 2023 (KR) 10-2023-0037936

(51) Int. Cl. H10B 51/30; H10B 51/20; H10B 51/40

(52) U.S. Cl. CPC H10B 51/30; H10B 51/20; H10B 51/40

(57) ABSTRACT

A semiconductor memory device includes a cell substrate, a plurality of gate electrodes sequentially stacked on the cell substrate and extending in a first direction, first and second channel structures extending in a second direction different from the first direction and penetrating the plurality of gate electrodes, and a bit line disposed on the plurality of gate electrodes. The first and second channel structures each include a ferroelectric layer, a channel layer, a gate insulating layer and a back gate electrode, which are sequentially disposed on side walls of the plurality of gate electrodes. The first channel structure and the second channel structure are adjacent to each other in the first direction and share a bit line.

### CROSS-REFERENCE TO RELATED APPLICATIONS

This application claims priority under 35 U.S.C. § 119 to Korean Patent Application No. 10-2022-0129814 filed on Oct. 11, 2022, and Korean Patent Application No. 10-2023-0037936 field on Mar. 23, 2023, the disclosures of which are incorporated by reference herein in their entireties.

### TECHNICAL FIELD

Embodiments of the present disclosure relate to a semiconductor memory device and an electronic system including the same. More specifically, embodiments of the present disclosure relate to a semiconductor memory device including memory cells arranged three-dimensionally and an electronic system including the same.

### DISCUSSION OF RELATED ART

Methods capable of increasing a data storage capacity of a semiconductor memory device capable of storing a large amount of data are being researched. As one method for increasing the data storage capacity of a semiconductor memory device, a semiconductor memory device including memory cells arranged three-dimensionally instead of memory cells arranged two-dimensionally has been proposed.

### SUMMARY

Aspects of the present disclosure provide a semiconductor memory device in which an inversion layer is formed in a channel layer by a voltage applied to a back gate electrode.

Aspects of the present disclosure also provide an electronic system including a semiconductor memory device in which an inversion layer is formed in a channel layer by a voltage applied to the back gate electrode.

According to some aspects of the present disclosure, there is provided a semiconductor device including cell substrate which includes a first side and a second side opposite to each other, a plurality of gate electrodes sequentially stacked on the first side of the cell substrate and extending in a first direction, first and second channel structures extending in a second direction different from the first direction, penetrating through the plurality of gate electrodes, and disposed adjacent to each other, a first contact disposed on the first channel structure, a first metal line disposed on the first contact, a second contact different from the first contact, disposed on the second channel structure, and a second metal line different from the first metal line, disposed on the second contact. Each of the first and second channel structures includes a back gate electrode extending in the second direction, a gate insulating layer disposed on a side wall of the back gate electrode, a channel layer disposed on an outer wall of the gate insulating layer, and a ferroelectric layer disposed on an outer wall of the channel layer. The first contact is electrically connected to the back gate electrode of the first channel structure, and the second contact is electrically connected to the back gate electrode of the second channel structure.

According to some aspects of the present disclosure, there is provided a semiconductor memory device including a cell substrate, a plurality of gate electrodes sequentially stacked on the cell substrate and extending in a first direction, first and second channel structures extending in a second direction different from the first direction and penetrating the plurality of gate electrodes, and a bit line disposed on the plurality of gate electrodes. The first and second channel structures each include a ferroelectric layer, a channel layer, a gate insulating layer and a back gate electrode, which are sequentially disposed on side walls of the plurality of gate electrodes, and the first channel structure and the second channel structure are adjacent to each other in the first direction and share a bit line.

According to some aspects of the present disclosure, there is provided an electronic system including a main board, a semiconductor memory device disposed on the main board, and a controller electrically connected to the semiconductor memory device, disposed on the main board. The semiconductor memory device includes a cell substrate, a plurality of gate electrodes sequentially stacked on the cell substrate and extending in a first direction, and first and second channel structures extending in a second direction different from the first direction, penetrating through the plurality of gate electrodes, and disposed adjacent to each other. The first and second channel structures each include a ferroelectric layer, a channel layer, a gate insulating layer and a back gate electrode that are sequentially disposed on side walls of the plurality of gate electrodes, and a voltage is independently applied to the back gate electrode of the first channel structure and the back gate electrode of the second channel structure.

### BRIEF DESCRIPTION OF THE DRAWINGS

The above and other aspects and features of the present disclosure will become more apparent by describing in detail embodiments thereof with reference to the accompanying drawings, in which:

FIG. 1 is an example block diagram for explaining a semiconductor memory device according to some example embodiments;

FIG. 2 is an example circuit diagram for explaining the semiconductor memory device according to some example embodiments;

FIG. 3 is a schematic layout diagram for explaining the semiconductor memory device according to some example embodiments;

FIG. 4 is a cross-sectional view taken along line I-I of FIG. 3;

FIGS. 5 to 8 are diagrams for explaining a read operation;

FIGS. 9 to 12 are diagrams for explaining a program operation;

FIGS. 13 and 14 are diagrams for explaining an erase operation;

FIG. 15 is a cross-sectional view for explaining the semiconductor memory device according to some example embodiments;

FIG. 16 is a schematic layout diagram for explaining the semiconductor memory device according to some example embodiments;

FIG. 17 is a cross-sectional view taken along line I-I of FIG. 16;

FIGS. 18 and 19 are schematic layout diagrams for explaining the semiconductor memory device according to some example embodiments;

FIG. 20 is a cross-sectional view taken along line I-I of FIGS. 18 and 19;

FIGS. 21 and 22 are cross-sectional views for explaining the semiconductor memory device according to some example embodiments;

FIG. 23 is a diagram for explaining the semiconductor memory device according to some example embodiments;

FIG. 24 is an example block diagram for explaining an electronic system according to some example embodiments;

FIG. 25 is an example perspective view for explaining an electronic system according to some example embodiments; and

FIG. 26 is a schematic cross-sectional view taken along line I-I of FIG. 25.

### DETAILED DESCRIPTION OF THE EMBODIMENTS

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

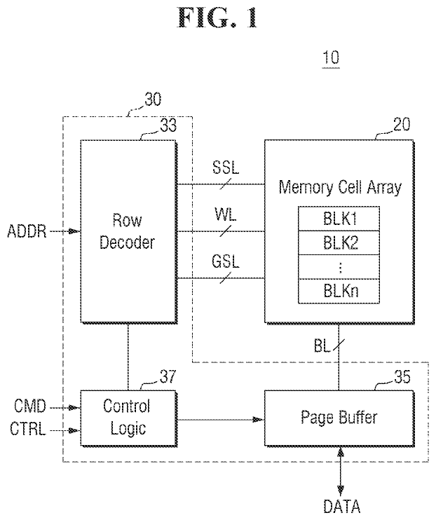

FIG. 1 is an example block diagram for explaining a semiconductor memory device according to some example embodiments.

Referring to FIG. 1, a semiconductor memory device 10 according to some example embodiments includes a memory cell array 20 and a peripheral circuit 30.

The memory cell array 20 may include a plurality of memory cell blocks BLK1 to BLKn, where n is a positive integer. Each of the memory cell blocks BLK1 to BLKn may include a plurality of memory cells. The memory cell array 20 may be connected to the peripheral circuit 30 through a bit line BL, a word line WL, at least one string selection line SSL, and at least one ground selection line GSL. For example, the memory cell blocks BLK1 to BLKn may be connected to the row decoder 33 through the word line WL, the string selection line SSL, and the ground selection line GSL. Also, the memory cell blocks BLK1 to BLKn may be connected to a page buffer 35 disposed in the peripheral circuit 30 through the bit line BL.

The peripheral circuit 30 may receive an address ADDR, a command CMD, and a control signal CTRL from outside of the semiconductor memory device 10, and may transmit and receive data DATA to and from an external device of the semiconductor memory device 10. The peripheral circuit 30 may include a control logic 37, a row decoder 33, and the page buffer 35. According to embodiments, the peripheral circuit 30 may further include various sub-circuits such as, for example, an I/O circuit, a voltage generation circuit that generates various voltages utilized for the operation of the semiconductor memory device 10, and an error correction circuit for correcting an error(s) of the data DATA that is read from the memory cell array 20.

The control logic 37 may be connected to the row decoder 33, the I/O circuit, and the voltage generation circuit. The control logic 37 may control the overall operation of the semiconductor memory device 10. The control logic 37 may generate various internal control signals used inside the semiconductor memory device 10 in response to the control signal CTRL. For example, the control logic 37 may adjust the voltage levels provided to the word line WL and the bit line BL when performing a memory operation such as a program operation or an erase operation.

The row decoder 33 may select at least one of the plurality of memory cell blocks BLK1 to BLKn in response to the address ADDR, and may select at least one word line WL, at least one string selection line SSL, and at least one ground selection line GSL of the selected memory cell blocks BLK1 to BLKn. Further, the row decoder 33 may transmit a voltage for performing the memory operation to the word line WL of the selected memory cell blocks BLK1 to BLKn.

The page buffer 35 may be connected to the memory cell array 20 through the bit line BL. The page buffer 35 may operate as a writer driver or a sense amplifier. For example, when the program operation is performed, the page buffer 35 may operate as the writer driver, and apply a voltage corresponding to the data DATA to be stored in the memory cell array 20 to the bit line BL. On the other hand, when performing the read operation, the page buffer 35 may operate as a sense amplifier to sense the data DATA stored in the memory cell array 20.

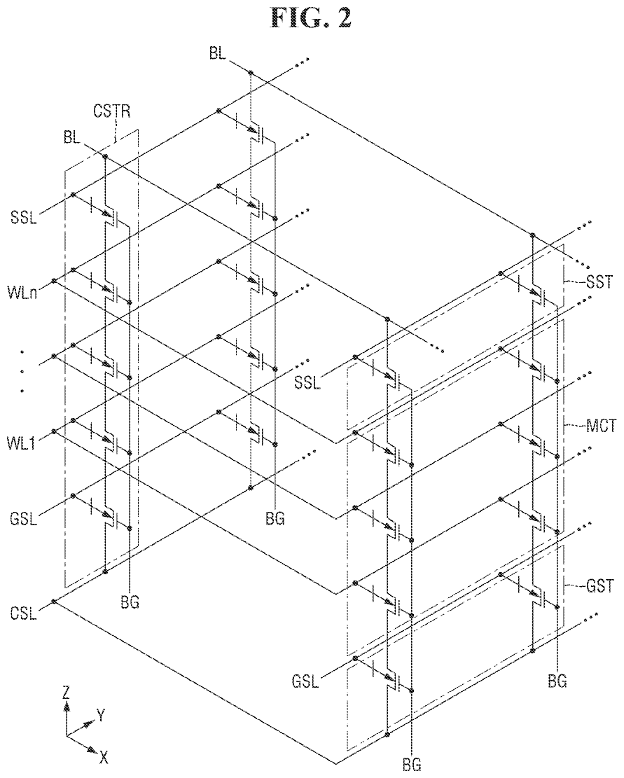

FIG. 2 is an example circuit diagram for explaining a semiconductor memory device according to some example embodiments.

Referring to FIG. 2, the memory cell array (e.g., 20 of FIG. 1) of the semiconductor device according to some example embodiments may include a common source line CSL, a plurality of bit lines BL, and a plurality of cell strings CSTR.

The plurality of bit lines BL may be arranged two-dimensionally in a plane in a first direction X and a second direction Y. For example, the bit lines BL are spaced apart from each other, arranged along the first direction X, and may each extend in the second direction Y. A plurality of cell strings CSTR may be connected in parallel to each bit line BL. The cell strings CSTR may be commonly connected to the common source line CSL. That is, the plurality of cell strings CS TR may be disposed between the bit lines BL and the common source line CSL.

Each cell string CSTR may include a ground selection transistor GST connected to the common source line CSL, a string selection transistor SST connected to the bit line BL, and a plurality of memory cell transistors MCT disposed between the ground selection transistor GST and the string selection transistor SST. Each memory cell transistor MCT may include a data storage element. The ground selection transistor GST, the string selection transistor SST and the memory cell transistors MCT may be connected in series. The ground selection transistor GST, the string selection transistor SST and the plurality of memory cell transistors MCT disposed between the ground selection transistor GST and the string selection transistor SST in each cell string CSTR may be connected a back gate line BG.

The common source line CSL may be commonly connected to sources of the ground selection transistors GST. Also, the ground selection line GSL, a plurality of word lines WL11 to WL1n, where n is a positive integer, and the string selection line SSL may be disposed between the common source line CSL and the bit line BL. The ground selection line GSL may be used as a gate electrode of the ground selection transistor GST, the word lines WL11 to WL1n may be used as gate electrodes of the memory cell transistors MCT, and the string selection line SSL may be used as the gate electrode of the string selection transistor SST.

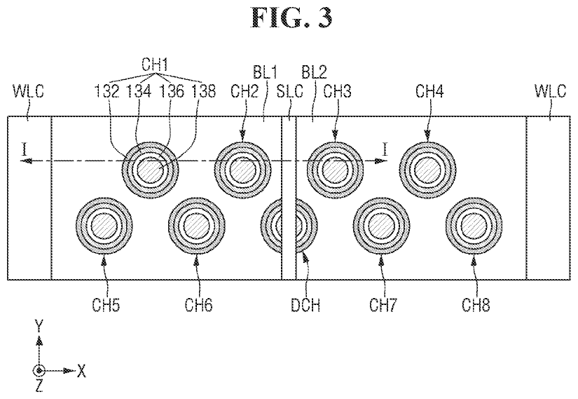

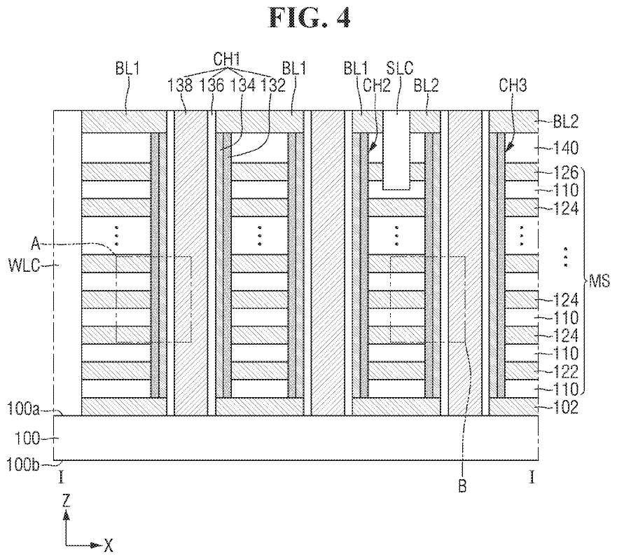

FIG. 3 is a schematic layout diagram for explaining a semiconductor memory device according to some example embodiments. FIG. 4 is a cross-sectional view taken along line I-I of FIG. 3. In FIG. 3, hatching of bit lines BL1 and BL2 is omitted.

Referring to FIGS. 3 and 4, the semiconductor memory device according to some example embodiments may include a cell substrate 100, a source layer 102, a mold structure MS, an interlayer insulating film 140, bit lines BL1 and BL2, a word line cut structure WLC, a string line cut structure SLC, channel structures CH1 to CH8, and a dummy channel structure DCH.

The cell substrate 100 may include a first side 100a and a second side 100b that are opposite to each other. The first side 100a of the cell substrate 100 and the second side 100b of the cell substrate 100 may be opposite to each other in a third direction Z. The third direction Z may intersect the first direction X and the second direction Y. The first direction X and the second direction Y may be a direction parallel to the first side 100a of the cell substrate 100, and may intersect each other (for example, perpendicular to each other). The third direction Z may be a direction perpendicular to the first side 100a of the cell substrate 100.

The cell substrate 100 may include, for example, a semiconductor substrate such as a silicon substrate, a germanium substrate or a silicon-germanium substrate. Alternatively, the cell substrate 100 may include, for example, a silicon-on-insulator (SOI) substrate, a germanium-on-insulator (GOI) substrate, and the like. In some example embodiments, the cell substrate 100 may include impurities. For example, the cell substrate 100 may include n-type impurities (e.g., phosphorus (P), arsenic (As), etc.).

The source layer 102 may be disposed on the first side 100a of the cell substrate 100. The source layer 102 may be provided as a common source line (CSL of FIG. 2) of the semiconductor memory device. The source layer 102 may include a conductive material such as, for example, doped polysilicon or metal.

The mold structure MS may be disposed on the first side 100a of the cell substrate 100. The mold structure MS may be disposed on the source layer 102. The source layer 102 may be interposed between the cell substrate 100 and the mold structure MS.

The mold structure MS may include a plurality of gate electrodes 122, 124 and 126 and a plurality of mold insulating films 110 that are stacked on the cell substrate 100. Each of the gate electrodes 122, 124 and 126 and each mold insulating film 110 may have a layered structure that extends parallel to the first side 100a of the cell substrate 100. The gate electrodes 122, 124 and 126 may be sequentially stacked on the cell substrate 100, while being spaced apart from each other by the mold insulating film 110.

The gate electrodes 122, 124 and 126 may be stacked in a stepwise manner. For example, the gate electrodes 122, 124, and 126 may extend in the first direction X with different lengths and have steps. In some example embodiments, the gate electrodes 122, 124 and 126 may also have steps in the second direction Y. Thus, each of the gate electrodes 122, 124 and 126 may include exposed regions that are exposed from other gate electrodes. The exposed regions may refer to regions in which the cell contact and the gate electrodes 122, 124 and 126 are in contact with each other.

In some example embodiments, the gate electrodes 122, 124 and 126 include at least one ground selection line 122, a plurality of word lines 124, and at least one string selection line 126 that are stacked sequentially on the cell substrate 100. The number, placement, and the like of the mold insulating film 110 and the gate electrodes 122, 124 and 126 are merely example and are not limited to those shown.

The gate electrodes 122, 124 and 126 may include a conductive material such as, for example, metal such as tungsten (W), molybdenum (Mo), ruthenium (Ru), cobalt (Co), and nickel (Ni), or a semiconductor material such as silicon. As an example, the gate electrodes 122, 124 and 126 may each include at least one of tungsten (W), molybdenum (Mo), and ruthenium (Ru). As another example, the gate electrodes 122, 124 and 126 may each include polysilicon. In an embodiment, the gate electrodes 122, 124 and 126 may be a multiple-film, unlike as shown in FIG. 4. For example, when the gate electrodes 122, 124 and 126 are multiple films, the gate electrodes 122, 124 and 126 may include a gate electrode barrier film and a gate electrode filling film. The gate electrode barrier film may include, for example, titanium nitride (TiN), and the gate electrode filling film may include, for example, tungsten (W), but embodiments are not limited thereto.

The mold insulating film 110 may include, for example, at least one of silicon oxide, silicon nitride, and silicon oxynitride. As an example, the mold insulating film 110 may include a silicon oxide film.

The interlayer insulating film 140 may be disposed on the first side 100a of the cell substrate 100. The interlayer insulating film 140 may cover the mold structure MS. The interlayer insulating film 140 may include, for example, at least one of silicon oxide, silicon oxynitride, and a low dielectric constant material (low-k) having a dielectric constant lower than that of silicon oxide.

Bit lines BL1 and BL2 may be disposed on the mold structure MS. The bit lines BL1 and BL2 may be disposed on the interlayer insulating film 140. The bit lines BL1 and BL2 may be arranged along the first direction X and extend in the second direction Y. The bit lines BL1 and BL2 may extend along the second direction Y, and may be electrically connected to the channel structures CH1 to CH8 arranged along the second direction Y.

The word line cut structure WLC may extend in the first direction X to cut the bit lines BL1 and BL2, the interlayer insulating film 140 and the mold structure MS. The mold structure MS may be divided by the word line cut structure WLC to form a plurality of memory cell blocks (e.g., BLK1 to BLKn of FIG. 1). The plurality of word line cut structures WLC may be two-dimensionally arranged in a plane in the first direction X and the second direction Y. For example, the word line cut structures WLC may each extend in the second direction Y, and be spaced apart from each other and arranged along the first direction X.

The word line cut structure WLC may include an insulating material such as, for example, at least one of silicon oxide, silicon nitride and silicon oxynitride.

The string line cut structure SLC may be disposed between the word line cut structures WLC. The string line cut structure SLC may extend in the first direction X to cut the bit lines BL1 and BL2, the interlayer insulating film 140 and the mold structure MS. The string line cut structure SLC may overlap the dummy channel structure DCH in the third direction Z.

The string line cut structure SLC may include an insulating material such as, for example, at least one of silicon oxide, silicon nitride and silicon nitride.

The plurality of channel structures CH1 to CH8 and the dummy channel structure DCH may be arranged in the form of a zigzag pattern. For example, the plurality of channel structures CH1 to CH8 and the dummy channel structure DCH may be alternately arranged in the first direction X and the second direction Y with each other. For example, the channel structures CH1 to CH8 may include first to eighth channel structures CH1 to CH8 and a dummy channel structure DCH arranged in the form of zigzag pattern between adjacent word line cut structures WLC. The first to fourth channel structures CH1 to CH4 may be arranged along the first direction X, and fifth and sixth channel structures CH5 and CH6, dummy channel structures DCH, and seventh and eighth channel structures CH7 and CH8 may be arranged along the first direction X.

The number, placement and the like of the plurality of channel structures CH1 to CH8 and the dummy channel structure DCH are merely an example, and are not limited to the shown example. For example, in some embodiments, the channel structures CH1 to CH8 may be arranged in the form of a honeycomb pattern.

In some example embodiments, bit lines BL1 and BL2 may be separated by the string line cut structure SLC. The channel structures CH1 to CH8 disposed between the word line cut structure WLC and the string line cut structure SLC may share the bit lines BL1 and BL2. For example, the first, second, fifth and sixth channel structures CH1, CH2, CH5 and CH6 may be commonly connected to the bit line BL1. The third, fourth, seventh and eighth channel structures CH3, CH4, CH7 and CH8 may be commonly connected to the bit line BL2.

The channel structures CH1 to CH8 may be disposed on the first side 100a of the cell substrate 100. The channel structures CH1 to CH8 may extend in a vertical direction (hereinafter, the third direction Z) intersecting the upper face of the cell substrate 100 to pass through the mold structure MS. For example, the channel structures CH1 to CH8 may have a pillar shape (for example, a cylindrical shape) extending in the third direction Z. Therefore, the channel structures CH1 to CH8 may intersect the gate electrodes 122, 124 and 126. The channel structures CH1 to CH8 and the dummy channel structure DCH may each have the same structure. The first channel structure CH1 will be described below as an example.

Hereinafter, the upper face, the lower side, the upper part, and the lower part are described based on the third direction Z.

The first channel structure CH1 may include a ferroelectric layer 132, a channel layer 134, a gate insulating layer 136 and a back gate electrode 138, which are sequentially stacked on side walls of the respective gate electrodes 122, 124 and 126. For example, a channel hole extending in the third direction Z and penetrating the mold structure MS may be formed. The ferroelectric layer 132, the channel layer 134, the gate insulating layer 136 and the back gate electrode 138 may be sequentially stacked inside the channel hole.

The back gate electrode 138 may extend in the third direction Z on the first side 100a of the cell substrate 100. The back gate electrode 138 may pass through the source layer 102, the mold structure MS, the interlayer insulating film 140, and the bit lines BL1 and BL2. The back gate electrode 138 may have, for example, a pillar shape. The back gate electrode 138 may be provides as a back gate of the semiconductor memory device (BG of FIG. 2).

The back gate electrode 138 may include, for example, metal such as tungsten (W), copper (Cu), aluminum (Al), titanium (Ti), tantalum (Ta), ruthenium (Ru), and gold (Au).

The gate insulating layer 136 may be disposed on side walls of the back gate electrode 138. The gate insulating layer 136 may extend along the side walls of the back gate electrode 138. The gate insulating layer 136 may wrap around and surround the back gate electrode 138. The gate insulating layer 136 may be disposed between the source layer 102, the mold structure MS, the interlayer insulating film 140, and the bit lines BL1 and BL2 and the back gate electrode 138. The gate insulating layer 136 may have a hollow barrel shape, e.g., a cylindrical shape.

The gate insulating layer 136 may include, for example, at least one of silicon oxide, silicon nitride, and silicon oxynitride.

The channel layer 134 may be disposed on the outer walls of the gate insulating layer 136. The channel layer 134 may extend along a part of the outer wall of the gate insulating layer 136. The channel layer 134 may wrap around and surround a part of the gate insulating layer 136. The channel layer 134 may be disposed between the mold structure MS and the interlayer insulating film 140 and the gate insulating layer 136. The channel layer 134 may extend in the third direction Z and intersect the gate electrodes 122, 124 and 126. The channel layer 134 may have, for example, a cylindrical shape.

One end of the channel layer 134 may be electrically connected to the source layer 102. For example, the lower face of the channel layer 134 in the third direction Z may be in contact with the source layer 102. Although the lower face of the channel layer 134 is shown to be coplanar with the upper face of the source layer 102, this is merely an example. As another example, the lower part of the channel layer 134 may be buried in the source layer 102, and the lower face of the channel layer 134 may be disposed lower than the upper face of the source layer 102.

The other end of the channel layer 134 may be electrically connected to the bit line BL1. In some example embodiments, the upper face of the channel layer 134 may be in contact (e.g., direct contact) with the bit line BL1. Although the upper face of the channel layer 134 is shown to be coplanar with the lower face of the bit line BL1, this is merely an example. As another example, the upper part of the channel layer 134 may be buried in the bit line BL1, and the upper face of the channel layer 134 may be disposed higher than the lower face of the bit line BL1. Similarly, the other end of the channel layer 134 of the third channel structure CH3 may be electrically connected to the bit line BL2. The upper face of the channel layer 134 of the third channel structure CH3 may be in contact (e.g., direct contact) with the bit line BL2.

The channel layer 134 may include, for example, semiconductor materials such as monocrystalline silicon, polycrystalline silicon, organic semiconductor matter, and carbon nanostructure.

The ferroelectric layer 132 may be disposed on the outer wall of the channel layer 134. The ferroelectric layer 132 may extend along the outer wall of the channel layer 134. The ferroelectric layer 132 may wrap around and surround the channel layer 134. The ferroelectric layer 132 may be disposed between the mold structure MS and the interlayer insulating film 140 and the channel layer 134. The ferroelectric layer 132 may have, for example, a cylindrical shape.

In some example embodiments, the upper face of the ferroelectric layer 132 and the upper face of the channel layer 134 may be disposed below the upper face of the back gate electrode 138.

The ferroelectric layer 132 may include ferroelectrics. The ferroelectrics means a material which has a spontaneous polarization and whose direction of polarization is changed by an external electric field. For example, the ferroelectric layer 132 may include at least one of hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide, and combinations thereof.

The semiconductor memory device according to some example embodiments may store information using varying polarized states of the ferroelectric layer 132 which includes ferroelectrics. The word lines 124 and the first to eighth channel structures CH1 to CH8 may constitute memory cells. For example, the varying polarized states of the ferroelectric layer 132 may be used to perform a program operation or an erase operation. As an example, negative charges may be disposed on the face of the ferroelectric layer 132 opposite to the channel layer 134 to perform a program operation. Also, the erase operation may be performed such that positive charges appear on the face of the ferroelectric layer 132 opposite to the channel layer 134.

In the semiconductor memory device according to some example embodiments, an inversion layer may be formed in the channel layer 134 by a voltage applied to the back gate electrode 138. That is, the channel layer 134 may be turned on by the voltage applied to the back gate electrode 138. The back gate electrodes 138 of the first to eighth channel structures CH1 to CH8 may each be driven independently.

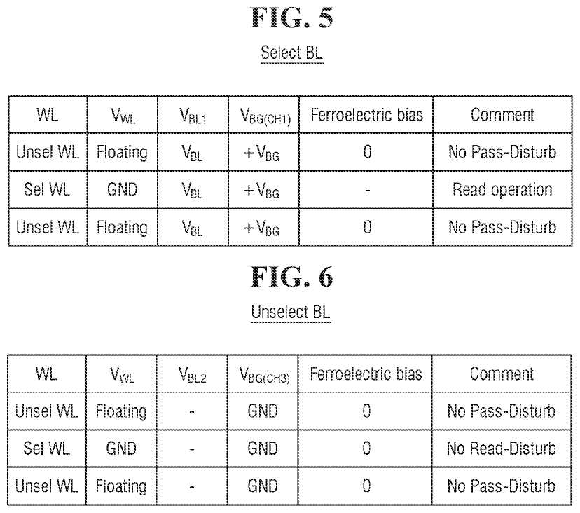

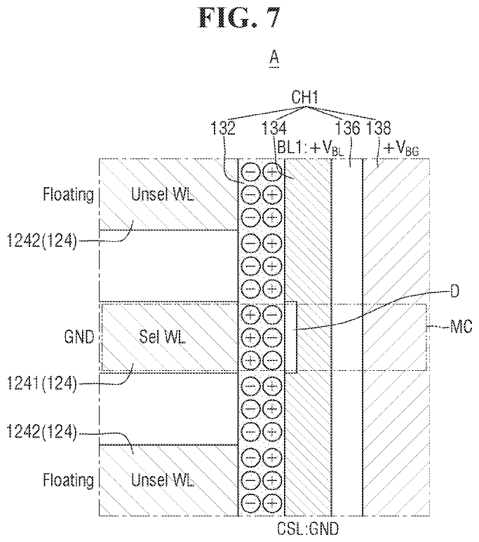

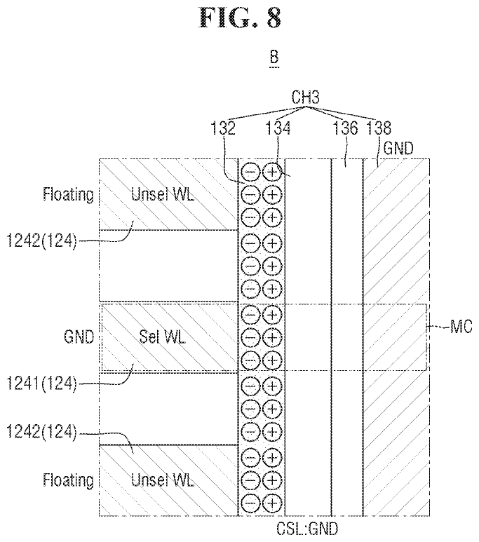

FIGS. 5 to 8 are diagrams for explaining the read operation. FIG. 5 shows an example of bias conditions of selected bit lines, and FIG. 6 shows an example of bias conditions of non-selected bit lines. FIG. 7 is an enlarged view of a portion A of FIG. 4, and FIG. 8 is an enlarged view of a portion B of FIG. 4.

Referring to FIGS. 5 and 7, the first channel structure CH1 may be connected to the selected bit line BL1. The first channel structure CH1 and the selected word line 1241 may form a selected memory cell MC.

A back gate voltage +V_{BG} may be applied to the back gate electrode 138 of the first channel structure CH1. An inversion layer may be formed on the channel layer 134 of the first channel structure CH1 by the back gate voltage +V_{BG}.

A ground voltage GND may be applied to the common source line CSL, and a bit line voltage +V_{BL} may be applied to the selected bit line BL1 to which the selected memory cell MC is connected. The ground voltage GND is applied to the selected word line 1241, and the non-selected word line 1242 may be brought into a floating state. Due to a potential difference between the ground voltage GND and the bit line voltage +V_{BL} which are applied to each of the common source line CSL electrically connected to one end of the channel layer 134 and the selected bit line BL1 electrically connected to the other end of the channel layer 134, a read current may flow along the third direction Z through the inversion layer of the channel layer 134. Due to the potential difference between the ground voltage GND and the back gate voltage +V_{BG} which are applied to each of the selected word line 1241 and the back gate electrode 138, a depletion region D may be formed in the channel layer 134 between the selected word line 1241 and the back gate electrode 138. Depending on the polarized state of the ferroelectric layer 132 of the selected memory cell MC, the depth of the depletion region D may be changed and the read current may vary. The selected memory cell MC may be read, accordingly.

At this time, the bias of the ferroelectric layer 132 on the side walls of the non-selected word lines 1242 is zero. Therefore, according to embodiments, a pass disturbance phenomenon due to application of the pass voltage to the non-selected word line 1242 may be prevented or reduced. That is, since the inversion layer of the channel layer 134 is formed by applying the back gate voltage +V_{BG} to the back gate electrode 138, the pass disturbance phenomenon due to application of the pass voltage to the non-selected word line 1242 may be prevented or reduced.

Referring to FIGS. 4, 6 and 8, the second channel structure CH2 may be connected to the selected bit line BL1. A third channel structure CH3 may be connected to a non-selected bit line BL2. The second channel structure CH2 and the word line 124, and the third channel structure CH3 and the word line 124 may each constitute a non-selected memory cell.

The ground voltage GND may be applied to the back gate electrode 138 of the third channel structure CH3. Therefore, the channel layer 134 of the third channel structure CH3 may be in an off-state. A non-selected bit line BL2 to which the third channel structure CH3 is connected may be in an off-state. Also, the ground voltage GND may be applied to the back gate electrode 138 of the second channel structure CH2. Accordingly, the channel layer 134 of the second channel structure CH2 and the channel layer 134 of the third channel structure CH3 may be in an off-state. The bias of the ferroelectric layer 132 on the side walls of the selected word line 1241 and the bias of the ferroelectric layer 132 on the side walls of the non-selected word lines 1242 may be zero.

Therefore, according to embodiments, the pass disturbance phenomenon caused by application of the boosting voltage to the non-selected bit line BL2 and application of the pass voltage to the non-selected word line 1242 may be prevented or reduced. Further, it is possible to prevent a read disturbance phenomenon caused by application of the boosting voltage to the non-selected bit line BL2 and application of the read voltage to the selected word line 1241.

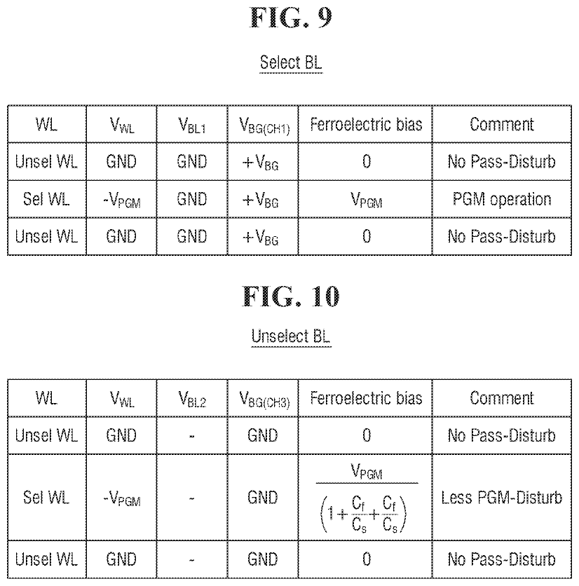

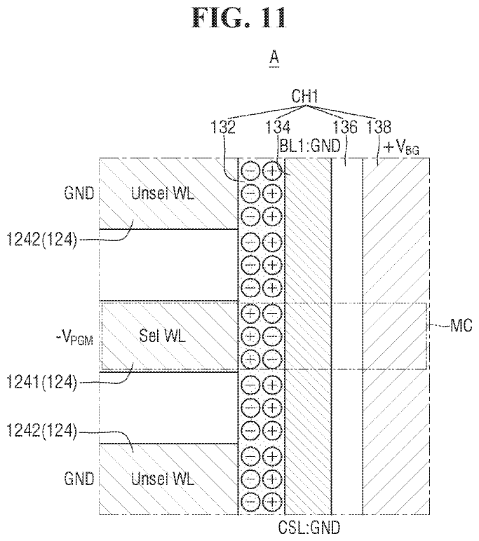

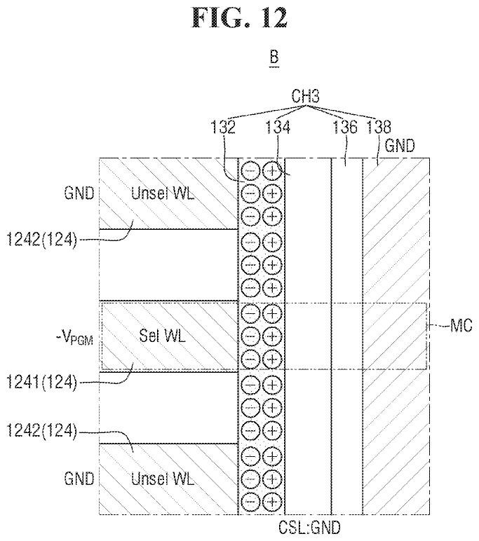

FIGS. 9 to 12 are diagrams for explaining the program operation. FIG. 9 shows an example of bias conditions of the selected bit line, and FIG. 10 shows an example of bias conditions of the non-selected bit line. FIG. 11 is an enlarged view of the portion A of FIG. 4, and FIG. 12 is an enlarged view of the portion B of FIG. 4.

Referring to FIGS. 9 and 11, the first channel structure CH1 may be connected to the selected bit line BL1. The first channel structure CH1 and the selected word line 1241 may form a selected memory cell MC.

A back gate voltage +V_{BG} may be applied to the back gate electrode 138 of the first channel structure CH1. An inversion layer may be formed on the channel layer 134 of the first channel structure CH1 by the back gate voltage +V_{BG}.

The ground voltage GND is applied to the common source line CSL, and the ground voltage GND may be applied to the selected bit line BL1 to which the selected memory cell MC is connected. Since the common source line CLS electrically connected to one end of the channel layer 134 and the selected bit line BL1 electrically connected to the other end of the channel layer 134 have the same potential, the current flowing in the third direction Z through the channel layer 134 is not generated.

A program voltage −V_{PGM} may be applied to the selected word line 1241 and the ground voltage GND may be applied to the non-selected word line 1242. Accordingly, the polarized state of the ferroelectric layer 132 of the selected memory cell MC may be changed. The selected memory cell MC may be programmed.

At this time, the bias of the ferroelectric layer 132 adjacent to the non-selected word lines 1242 is zero. Therefore, according to embodiments, the pass disturbance phenomenon due to application of the pass voltage to the non-selected word lines 1242 may be prevented or reduced. That is, since the inversion layer of the channel layer 134 is formed by applying the back gate voltage +V_{BG} to the back gate electrode 138, a pass disturbance phenomenon due to application of the pass voltage to the non-selected word line 1242 may be prevented or reduced.

Referring to FIGS. 4, 10 and 12, the second channel structure CH2 may be connected to the selected bit line BL1. A third channel structure CH3 may be connected to a non-selected bit line BL2. The second channel structure CH2 and the word line 124, and the third channel structure CH3 and the word line 124 may each constitute a non-selected memory cell.

The ground voltage GND may be applied to the back gate electrode 138 of the third channel structure CH3. The non-selected bit line BL2 to which the third channel structure CH3 is connected may be in an off-state. Also, the ground voltage GND may be applied to the back gate electrode 138 of the second channel structure CH2. Accordingly, the channel layer 134 of the second channel structure CH2 and the channel layer 134 of the third channel structure CH3 may be in an off-state. The bias of the ferroelectric layer 132 on the side walls of the non-selected word lines 1242 may be zero. Therefore, according to embodiments, the pass disturbance phenomenon due to application of the pass voltage to the non-selected word line 1242 may be prevented or reduced.

Also, the bias on the side walls of the selected word line 1241 is

$$\frac{{V}_{P G M}}{( 1 + \frac{{c}_{f}}{{c}_{s}} + \frac{{c}_{f}}{{c}_{g}} )} .$$

Here, C_{f}, Cₛ, and C_{g} are ferroelectric capacitance, channel capacitance, and gate insulating layer capacitance, respectively. Therefore, according to embodiments, the program disturbance phenomenon caused by the application of the boosting voltage to the non-selected bit line BL2 and the application of the program voltage to the selected word line 1241 may be prevented or reduced.

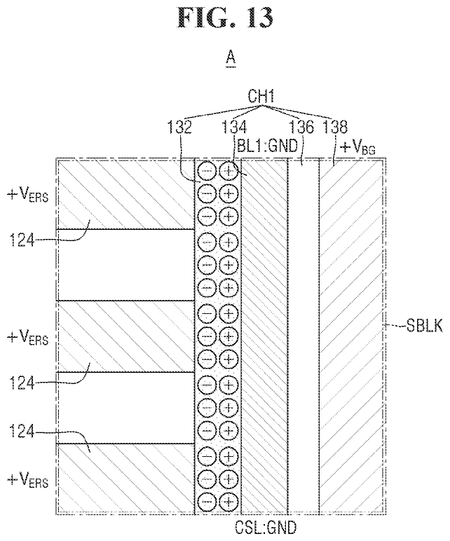

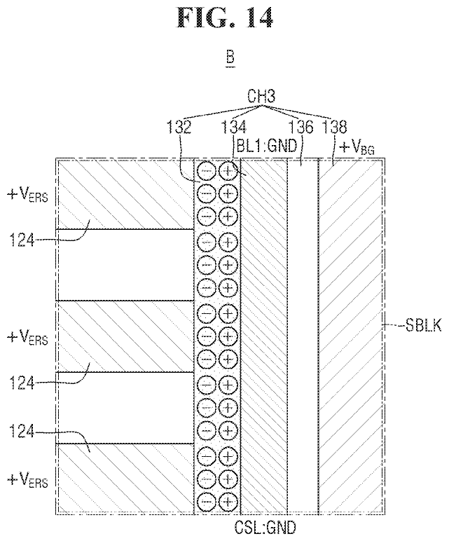

FIGS. 13 and 14 are diagrams for explaining the erase operation. FIG. 13 is an enlarged view of the portion A of FIG. 4, and FIG. 14 is an enlarged view of the portion B of FIG. 4.

Referring to FIGS. 4, 13 and 14, the back gate voltage +V_{BG} may be applied to the back gate electrodes 138 of the channel structures CH1 to CH8 included in the selected memory block SBLK. An inversion layer may be formed on the channel layers 134 of the channel structures CH1 to CH8 by the back gate voltage +V_{BG}.

The ground voltage GND may be applied to the common source line CSL, and the ground voltage GND may be applied to the bit lines BL1 and BL2 included in the selected memory block SBLK. An erase voltage +V_{ERS} may be applied to all word lines 124 included in the selected memory block SBLK. Accordingly, the polarized state of the ferroelectric layers 132 of all memory cells included in the selected memory block SBLK may be changed to a specific polarized state. All memory cells may be erased.

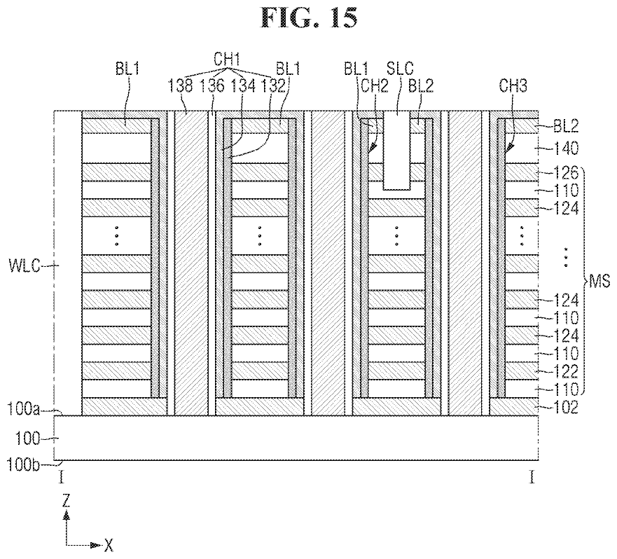

FIG. 15 is a cross-sectional view for explaining a semiconductor memory device according to some example embodiments. For convenience of explanation, a further description of components and technical elements previously described with reference to FIGS. 1 to 14 may be omitted.

Referring to FIG. 15, in the semiconductor memory device according to some example embodiments, a channel layer 134 may extend alongside walls of the gate insulating layer 136. The channel layer 134 may wrap around and surround the gate insulating layer 136. The channel layer 134 may further extend along the upper faces of the bit lines BL1 and BL2. The channel layer 134 may be in contact with the upper faces of the bit lines BL1 and BL2.

The channel layer 134 of the first channel structure CH1 may be connected with the channel layer 134 of the second channel structure CH2. The channel layer 134 of the first channel structure CH1 and the channel layer 134 of the second channel structure CH2 may be in contact (e.g., direct contact) with each other.

The upper face of the ferroelectric layer 132 may be disposed below the upper face of the channel layer 134.

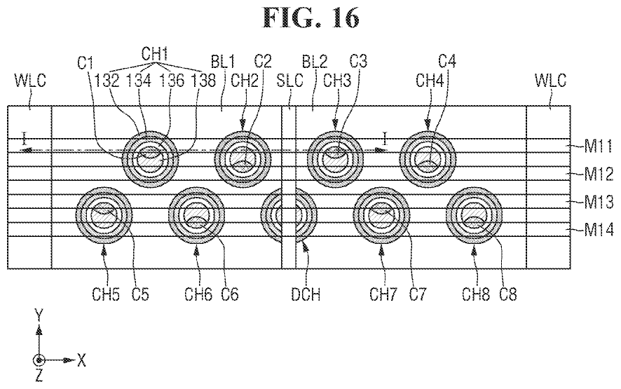

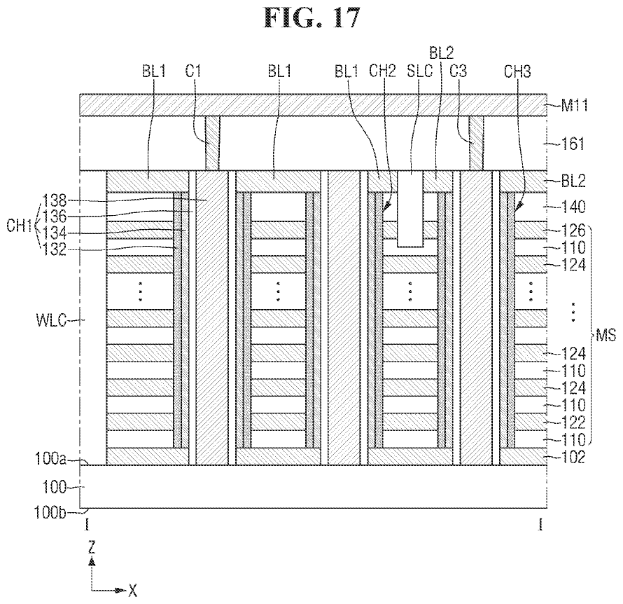

FIG. 16 is a schematic layout diagram for explaining a semiconductor memory device according to some example embodiments. FIG. 17 is a cross-sectional view taken along line I-I of FIG. 16. For convenience of explanation, a further description of components and technical aspects previously described with reference to FIGS. 1 to 14 may be omitted. In FIG. 16, hatching of bit lines BL1 and BL2 and metal lines M11 to M14 is omitted.

Referring to FIGS. 16 and 17, in the semiconductor memory device according to some example embodiments, the back gate electrodes 138 of the channel structures CH1, CH2, CH5, CH6, or CH3, CH4, CH7, CH8 disposed between the word line cut structure WLC and the string line cut structure SLC adjacent to each other may be independently driven.

The back gate electrodes 138 of the channel structures CH1, CH2, CH5, CH6 or CH3, CH4, CH7, CH8 disposed between the word line cut structure WLC and the string line cut structure SLC adjacent to each other may each be electrically connected to the metal lines M11 to M14, which are different from each other. For example, channel structures CH1 to CH8 disposed on the different sides on the basis of the string line cut structure SLC may share the metal lines M11 to M14 disposed between the word line cut structures WLC adjacent to each other.

For example, the semiconductor memory device according to some example embodiments may include a plurality of different contacts C1 to C8 and a plurality of different metal lines M11 to M14. For example, each of the first to eighth contacts C1 to C8 may be disposed on the back gate electrode 138 of each of the first to eighth channel structures CH1 to CH8. Each of the first to eighth contacts C1 to C8 may be in contact (e.g., direct contact) with the back gate electrode 138 of each of the first to eighth channel structures CH1 to CH8. Each of the first to eighth contacts C1 to C8 may be electrically connected to the back gate electrode 138 of each of the first to eighth channel structures CH1 to CH8.

The first metal line M11 may be electrically connected to the first and third contacts C1 and C3. The second metal line M12 may be electrically connected to the second and fourth contacts C2 and C4. The third metal line M13 may be electrically connected to the fifth and seventh contacts C5 and C7. The fourth metal line M14 may be electrically connected to the sixth and eighth contacts M6 and M8.

In some example embodiments, the first to eighth contacts C1 to C8 and the first to fourth metal lines M11 to M14 may be disposed on one side of the cell substrate 100. The first to fourth metal lines M11 to M14 may be formed on the same metal level.

For example, the first to eighth contacts C1 to C8 and the first to fourth metal lines M11 to M14 may be disposed on the first side 100a of the cell substrate 100. An interlayer insulating film 161 may be disposed on the mold structure MS. The first to fourth metal lines M11 to M14 may be disposed on the interlayer insulating film 161. A plurality of contacts C1 to C8 penetrate through the interlayer insulating film 161, and may be electrically connected to the back gate electrodes 138 of the plurality of channel structures CH1 to CH8 and the plurality of metal lines M11 to M14.

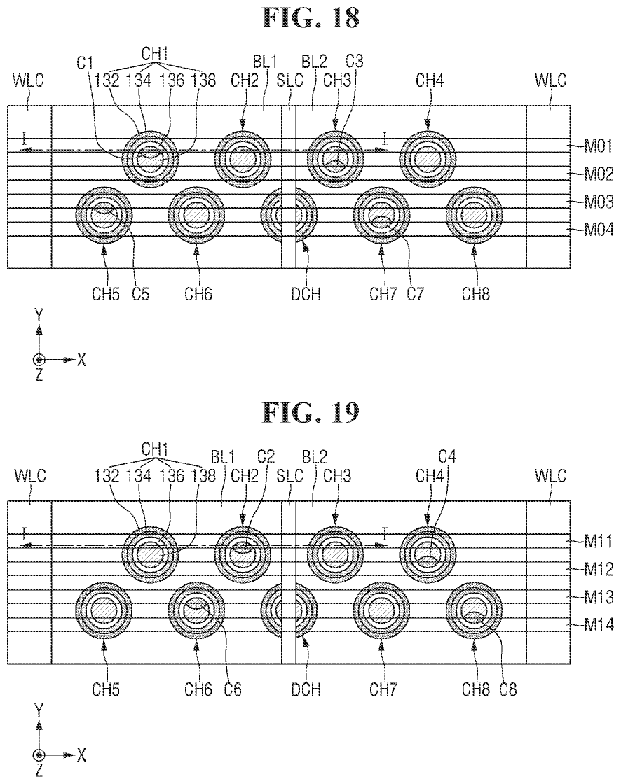

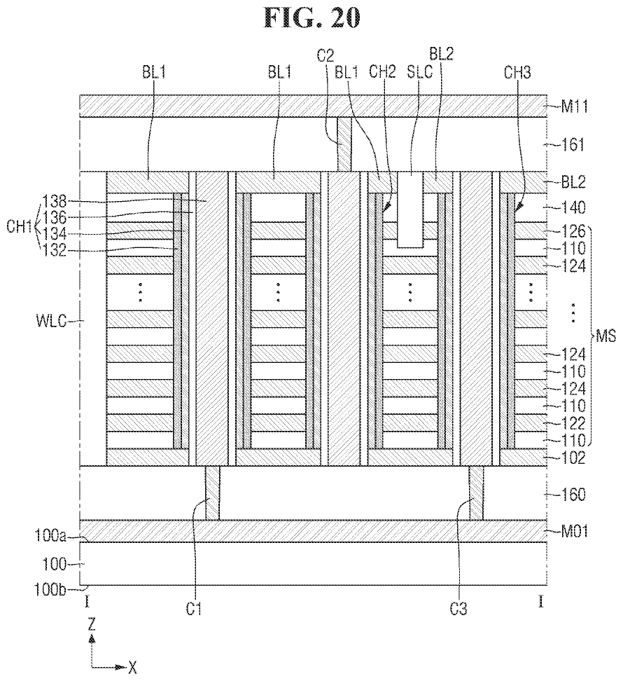

FIGS. 18 and 19 are schematic layout diagrams for explaining a semiconductor memory device according to some example embodiments. FIG. 20 is a cross-sectional view taken along line I-I of FIGS. 18 and 19. For convenience of explanation, a further description of components and technical aspects previously described with reference to FIGS. 1 to 17 may be omitted. In FIGS. 18 and 19, hatching of bit lines BL1 and BL2 and metal lines M11 to M14 and M01 to M04 is omitted.

Referring to FIGS. 18 to 20, in some example embodiments, the back gate electrodes 138 of the channel structures CH1 to CH8 disposed between adjacent word line structures WLC may each be driven independently. The back gate electrodes 138 of the channel structures CH1 to CH8 disposed between the adjacent word line structures WLC may be electrically connected to the metal lines M11 to M14 and M01 to M04, which are different from each other.

For example, the semiconductor memory device according to some example embodiments may include a plurality of different contacts C1 to C8 and a plurality of different metal lines M11 to M14 and M01 to M04. For example, the first metal line M11 may be electrically connected to the second contact C2. The second metal line M12 may be electrically connected to the fourth contact C4. The third metal line M13 may be electrically connected to the sixth contact C6. The fourth metal line M14 may be electrically connected to the eighth contact M8. The fifth metal line M01 may be electrically connected to the first contact C1. The sixth metal line M02 may be electrically connected to the third contact C3. The seventh metal line M03 may be electrically connected to the fifth contact C5. The eighth metal line M04 may be electrically connected to the seventh contact C7.

In some example embodiments, some of the first to eighth contacts C1 to C8 and the first to eighth metal lines M11 to M14 and M01 to M04 and the rest may be disposed on the different metal level.

For example, the second, fourth, sixth and eighth contacts C2, C4, C6 and C8 and the first to fourth metal lines M11 to M14 may be disposed on the plurality of gate electrodes 122, 124 and 126. The first, third, fifth and seventh contacts C1, C3, C5 and C7 and the fifth to eighth metal lines M01 to M04 may be disposed between the first side 100a of the cell substrate 100 and the plurality of gate electrodes 122, 124 and 126. The interlayer insulating layer 160 may be disposed between the mold structure MS and the second side 100b of the cell substrate 100. The fifth to eighth metal lines M01 to M04 may be disposed on the interlayer insulating layer 160. The first, third, fifth and seventh contacts C1, C3, C5 and C7 penetrate the interlayer insulating layer 160, and may be electrically connected to the back gate electrode 138 of the first, third, fifth and seventh channel structures CH1, CH3, CH5 and CH7 and the fifth to eighth metal lines M01 to M04.

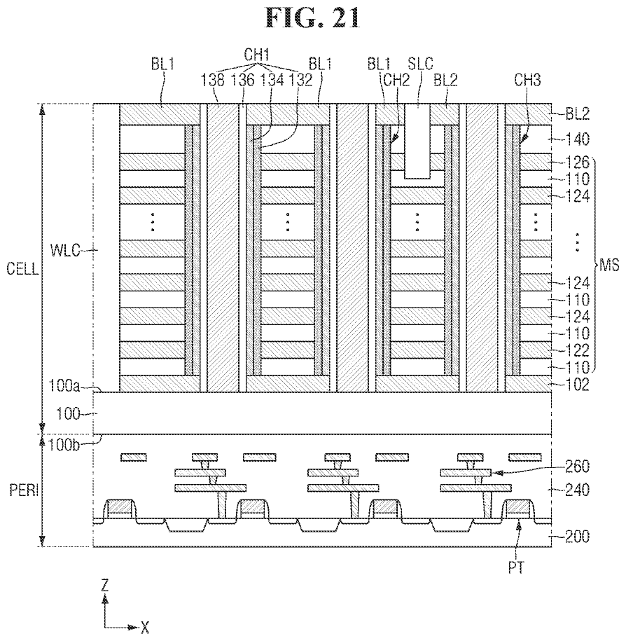

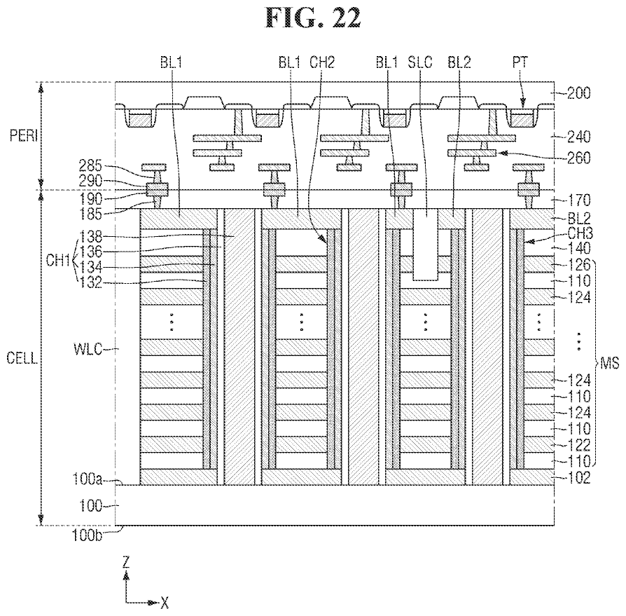

FIGS. 21 and 22 are cross-sectional views for explaining a semiconductor memory device according to some example embodiments. For convenience of explanation, a further description of components and technical aspects previously described with reference to FIGS. 1 to 14 may be omitted.

Referring to FIGS. 21 and 22, the semiconductor memory device according to some example embodiments may include a cell structure CELL and a peripheral circuit structure PERI.

The cell structure CELL may include the cell substrate 100, the source layer 102, the mold structure MS, the interlayer insulating film 140, the bit lines BL1 and BL2, the word line cut structure WLC, the string line cut structure SLC, the channel structures CH1 to CH8, and the dummy channel structures DCH described with reference to FIGS. 1 to 14. The cell structure CELL may be stacked on the peripheral circuit structure PERI.

The peripheral circuit structure PERI may include a peripheral circuit substrate 200, a peripheral circuit element PT, and a peripheral circuit wiring structure 260.

The peripheral circuit substrate 200 may include a semiconductor substrate such as, for example, a silicon substrate, a germanium substrate or a silicon-germanium substrate. Alternatively, the peripheral circuit substrate 200 may include, for example, a Silicon-On-Insulator (SOI) substrate, a Germanium-On-Insulator (GOI) substrate or the like.

The peripheral circuit element PT may be formed on the peripheral circuit substrate 200. The peripheral circuit element PT may constitute a peripheral circuit (e.g., 30 of FIG. 1) that controls the operation of the semiconductor memory device. For example, the peripheral circuit element PT may include a control logic (e.g., 37 of FIG. 1), a row decoder (e.g., 22 of FIG. 1), a page buffer (e.g., 35 of FIG. 1), and the like. In the following description, a surface of the peripheral circuit substrate 200 on which the peripheral circuit element PT is disposed may be referred to as a front side of the peripheral circuit substrate 200. In contrast, a surface of the peripheral circuit substrate 200 opposite to the front side of the peripheral circuit substrate 200 may be referred to as a back side of the peripheral circuit substrate 200.

The peripheral circuit element PT may include, for example, a transistor. For example, the peripheral circuit element PT may include not only various active elements such as a transistor, but also various passive elements such as a capacitor, a resistor and an inductor.

A peripheral circuit wiring structure 260 may be formed on the peripheral circuit element PT. For example, an inter-wiring insulating film 240 may be formed on the front side of the peripheral circuit substrate 200, and the peripheral circuit wiring structure 260 may be formed inside the inter-wiring insulating film 240. The peripheral circuit wiring structure 260 may be electrically connected to the peripheral circuit element PT. The number of layers, placement, and the like of the shown peripheral circuit wiring structure 260 are merely examples, and are not limited thereto.

Referring to FIG. 21, in some example embodiments, the peripheral circuit structure PERI may be disposed on the second side 100b of the cell substrate 100. The cell structure CELL may be disposed on the inter-wiring insulating film 240 of the peripheral circuit structure PERI. For example, the cell wiring structure of the cell structure CELL may be disposed on the mold structure MS, and the cell wiring structure and the peripheral circuit wiring structure 260 may be electrically connected by a through plug that penetrates the mold structure MS and the cell substrate 100.

Referring to FIG. 22, in some example embodiments, the peripheral circuit structure PERI may be disposed on the first side 100a of the cell substrate 100. The peripheral circuit structure PERI may be disposed on the interlayer insulating layer 170 of the cell structure CELL.

A first bonding metal 190 may be disposed on the uppermost metal layer of the cell structure CELL. A second bonding metal 290 may be disposed on the uppermost metal layer of the peripheral structure PERI.

The first bonding metal 190 and the second bonding metal 290 may be bonded together. Accordingly, the cell structure CELL and the peripheral structure PERI may be bonded together. When the first bonding metal 190 and the second bonding metal 290 are formed of copper (Cu), the bonding method may be a Cu—Cu bonding method.

The first bonding metal 190 may be connected to the bit line BL through the first bonding contact 185. The second bonding metal 290 may be connected to the peripheral circuit elements PT through the second bonding contact 285. Accordingly, the peripheral structure PERI and the cell structure CELL may be electrically connected to each other.

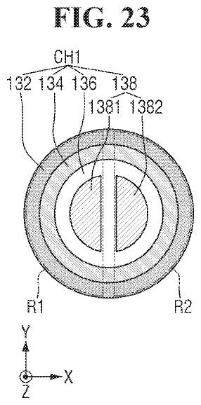

FIG. 23 is a diagram for explaining a semiconductor memory device according to some example embodiments. For convenience of explanation, a further description of components and technical aspects previously described with reference to FIGS. 1 to 14 may be omitted. The description of the first channel structure CH1 provided below a may also be applied to the second to eighth channel structures CH2 to CH8.

Referring to FIG. 23, in a semiconductor memory device according to some example embodiments, a first channel structure CH1 may include a plurality of back gate electrodes 138. The plurality of back gate electrodes 138 may be separated.

For example, the back gate electrode 138 of the first channel structure CH1 may include a first back gate electrode 1381 and a second back gate electrode 1382 that are separated from each other. The first back gate electrode 1381 and the second back gate electrode 1382 may each be driven independently. A voltage may be applied to the first back gate electrode 1381 to form an inversion layer on the channel layer 134 of a first region R1, and a voltage may be applied to the second back gate electrode 1382 to form an inversion layer on the channel layer 134 of a second region R2. The first and second regions R1 and R2 may be activated according to the voltage applied to the first and second back gate electrodes 1381 and 1382. Since an inversion layer is formed on the channel layer 134 of the first and second regions R1 and R2 using the first and second back gate electrodes 1381 and 1382, the channel layer 134 may be electrically separated without physical damage.

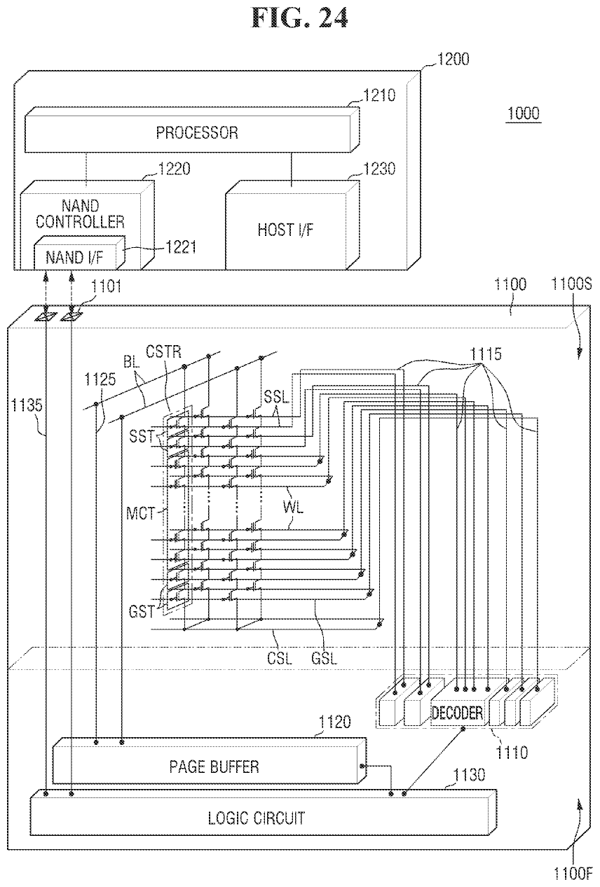

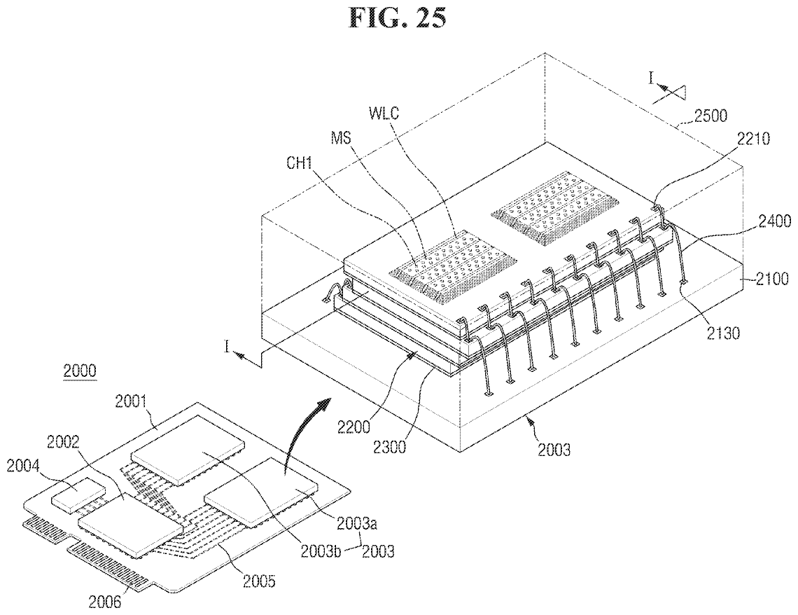

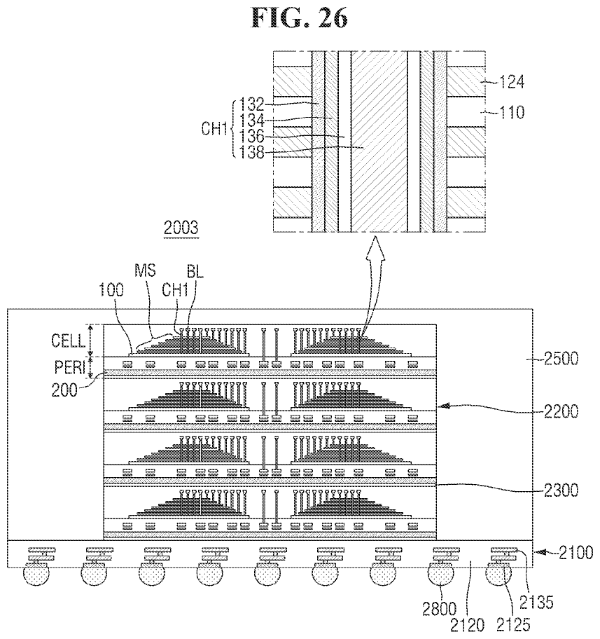

FIG. 24 is an example block diagram for describing an electronic system according to some example embodiments. FIG. 25 is an example perspective view for describing an electronic system according to some example embodiments. FIG. 26 is a schematic cross-sectional view taken along line I-I of FIG. 25. FIGS. 25 and 26 exemplarily show the first channel structure CH1.

Referring to FIG. 24, an electronic system 1000 according to some example embodiments may include a semiconductor memory device 1100 and a controller 1200 that is electrically connected to the semiconductor memory device 1100. The electronic system 1000 may be a storage device that includes one or multiple semiconductor memory devices 1100, or an electronic device that includes the storage device. For example, the electronic system 1000 may be a solid state drive (SSD) device, a universal serial bus (USB) device, a computing system, a medical device or a communication device that includes one or multiple semiconductor memory devices 1100.

The semiconductor memory device 1100 may be a non-volatile memory device (e.g., a NAND flash memory device), and may be, for example, the semiconductor memory device described above with reference to FIGS. 1 to 23. The semiconductor memory device 1100 may include a first structure 1100F and a second structure 1100S disposed on the first structure 1100F.

The first structure 1100F may be a peripheral circuit structure that includes a decoder circuit 1110 (e.g., the row decoder 33 of FIG. 1), a page buffer 1120 (e.g., the page buffer 35 of FIG. 1), and a logic circuit 1130 (e.g., the control logic 37 of FIG. 1). The first structure 1100F may correspond to, for example, the peripheral circuit structure PERI described above with reference to FIGS. 21 and 22.

The second structure 11005 may include the common source line CSL, the plurality of bit lines BL, and the plurality of cell strings CSTR described above with reference to FIG. 2. The cell strings CSTR may be connected to the decoder circuit 1110 through a word line WL, at least one string selection line SSL, and at least one ground selection line GSL. In addition, the cell strings CSTR may be connected to the page buffer 1120 through the bit line BL. The second structure 1100S may correspond to, for example, the cell structure CELL described above with reference to FIGS. 1 to 23.

In some example embodiments, the common source line CSL and the cell strings CSTR may be electrically connected to the decoder circuit 1110 through first connection wirings 1115 extending from the first structure 1100F to the second structure 1100S.

In some example embodiments, the bit lines BL may be electrically connected to the page buffer 1120 through the second connection wirings 1125.

The semiconductor memory device 1100 may communicate with the controller 1200 through I/O pads 1101 electrically connected to the logic circuit 1130 (e.g., the control logic 37 of FIG. 1). The I/O pads 1101 may be electrically connected to the logic circuit 1130 through the I/O connection wiring 1135 extending from the inside of the first structure 1100F to the second structure 1100S.

The controller 1200 may include a processor 1210, a NAND controller 1220, and a host interface 1230. In some example embodiments, the electronic system 1000 may include a plurality of semiconductor memory devices 1100, and in this case, the controller 1200 may control the plurality of semiconductor memory devices 1100.

The processor 1210 may control the operation of the overall electronic system 1000 including the controller 1200. The processor 1210 may operate according to a predetermined firmware, and may control the NAND controller 1220 to access the semiconductor memory device 1100. The NAND controller 1220 may include a NAND interface 1221 that processes communication with the semiconductor memory device 1100. Control command for controlling the semiconductor memory device 1100, data to be recorded in the memory cell transistors MCT of the semiconductor memory device 1100, data to be read from the memory cell transistors MCT of the semiconductor memory device 1100, and the like may be transmitted through the NAND interface 1221. The host interface 1230 may provide a communication function between the electronic system 1000 and an external host. When receiving the control command from the external host through the host interface 1230, the processor 1210 may control the semiconductor memory device 1100 in response to the control command.

Referring to FIGS. 25 and 26, the electronic system 2000 according to some example embodiments may include a main board 2001, a main controller 2002 mounted on the main board 2001, one or more semiconductor packages 2003, and a DRAM 2004. The semiconductor package 2003 and the DRAM 2004 may be connected to the main controller 2002 by wiring patterns 2005 formed on the main board 2001.

The main board 2001 may include a connector 2006 including a plurality of pins, that may be coupled to an external host. In the connector 2006, the number and placement of the plurality of pins may vary depending on the communication interface between the electronic system 2000 and the external host. In some example embodiments, the electronic system 2000 may communicate with the external host according to any one of interfaces such as, for example, Universal Serial Bus (M-Phy for USB), Peripheral Component Interconnect Express (PCI-Express), Serial Advanced Technology Attachment (SATA), and Universal Flash Storage (UFS). In some example embodiments, the electronic system 2000 may operate using power supplied from the external host through the connector 2006. The electronic system 2000 may further include a Power Management Integrated Circuit (PMIC) that distributes the power supplied from the external host to the main controller 2002 and the semiconductor package 2003.

The main controller 2002 may record data on the semiconductor package 2003 or read data from the semiconductor package 2003, and may increase the operating speed of the electronic system 2000.

The DRAM 2004 may be a buffer memory that relieves a speed difference between the semiconductor package 2003, which is a data storage space, and the external host. The DRAM 2004 included in the electronic system 2000 may also operate as a type of cache memory, and may also provide a space for temporarily storing data in the control operation on the semiconductor package 2003. When the DRAM 2004 is included in the electronic system 2000, the main controller 2002 may further include a DRAM controller that controls the DRAM 2004, in addition to a NAND controller that controls the semiconductor package 2003.

The semiconductor package 2003 may include a first semiconductor package 2003a and a second semiconductor package 2003b that are spaced apart from each other. The first semiconductor package 2003a and the second semiconductor package 2003b may each be a semiconductor package that includes a plurality of semiconductor chips 2200. The first semiconductor package 2003a and the second semiconductor package 2003b may each include a package substrate 2100, semiconductor chips 2200 disposed on the package substrate 2100, adhesive layers 2300 disposed on the lower faces of each of the semiconductor chips 2200, a connecting structure 2400 that electrically connects the semiconductor chips 2200 and the package substrate 2100, and a molding layer 2500 that covers the semiconductor chips 2200 and the connecting structure 2400 on the package substrate 2100.

The package substrate 2100 may be a printed circuit board that includes package upper pads 2130. Each semiconductor chip 2200 may include an I/O pad 2210. The I/O pad 2210 may correspond to the I/O pad 1101 of FIG. 23.

In some example embodiments, the connecting structure 2400 may be a bonding wire that electrically connects the I/O pad 2210 and the package upper pads 2130. Therefore, in each of the first semiconductor package 2003a and the second semiconductor package 2003b, the semiconductor chips 2200 may be electrically connected to each other by a bonding wire method, and may be electrically connected to the package upper pads 2130 of the package substrate 2100. In some example embodiments, in each of the first semiconductor package 2003a and the second semiconductor package 2003b, the semiconductor chips 2200 may be electrically connected to each other by a connecting structure including a through electrode (Through Silicon Via, TSV) instead of the connecting structure 2400 of the bonding wire method.

In some example embodiments, the main controller 2002 and the semiconductor chips 2200 may also be included in a single package. In some example embodiments, the main controller 2002 and the semiconductor chips 2200 are mounted on a separate interposer substrate different from the main board 2001, and the main controller 2002 and the semiconductor chips 2200 may also be connected to each other by the wiring formed on the interposer substrate.

In some example embodiments, the package substrate 2100 may be a printed circuit board. The package substrate 2100 may include a package substrate body portion 2120, package upper pads 2130 disposed on an upper face of the package substrate body portion 2120, lower pads 2125 disposed on a lower face of the package substrate body portion 2120 or exposed through the lower face, and internal wirings 2135 that electrically connect the package upper pads 2130 and the lower pads 2125 inside the package substrate body portion 2120. The package upper pads 2130 may be electrically connected to the connecting structures 2400. The lower pads 2125 may be connected to the wiring patterns 2005 of the main board 2001 of the electronic system 2000 through the conductive connections 2800, as shown in FIGS. 25 and 26.

In the electronic system according to some example embodiments, each of the semiconductor chips 2200 may include the semiconductor memory device described above with reference to FIGS. 1 to 22. For example, each of the semiconductor chips 2200 may include a peripheral circuit structure PERI, and a cell structure CELL stacked on the peripheral circuit structure PERI. For example, the peripheral circuit structure PERI may include the peripheral circuit substrate 200 and the peripheral circuit wiring structure 260 described above with reference to FIGS. 21 and 22. Also, for example, the cell structure CELL may include the cell substrate 100, the mold structure MS, the channel structures CH1 to CH8, and the bit line BL described above with reference to FIGS. 3 to 23. Also, the channel structures CH1 to CH8 may include a ferroelectric layer 132, a channel layer 134, a gate insulating layer 136, and a back gate electrode 138. An inversion layer may be formed on the channel layer 134 by a voltage applied to the back gate electrode 138.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A semiconductor memory device, comprising:
a cell substrate comprising a first side and a second side disposed opposite to each other;
a plurality of gate electrodes sequentially stacked on the first side of the cell substrate and extending in a first direction;
first and second channel structures extending in a second direction different from the first direction, penetrating through the plurality of gate electrodes, and disposed adjacent to each other;
a first contact disposed on the first channel structure;
a first metal line disposed on the first contact;
a second contact different from the first contact, disposed on the second channel structure; and
a second metal line different from the first metal line, disposed on the second contact,
wherein each of the first and second channel structures comprises:
a back gate electrode extending in the second direction;
a gate insulating layer disposed on a side wall of the back gate electrode;
a channel layer disposed on an outer wall of the gate insulating layer; and
a ferroelectric layer disposed on an outer wall of the channel layer,
wherein the first contact is electrically connected to the back gate electrode of the first channel structure, and
the second contact is electrically connected to the back gate electrode of the second channel structure.

2. The semiconductor memory device of claim 1,
wherein the first and second metal lines are disposed on the first side of the cell substrate.

3. The semiconductor memory device of claim 1,
wherein the first and second metal lines are disposed on the different metal level.

4. The semiconductor memory device of claim 1,
wherein the first metal line is disposed between the first side of the cell substrate and the plurality of gate electrodes, and
the second metal line is disposed on the plurality of gate electrodes.

5. The semiconductor memory device of claim 1, further comprising:
a peripheral circuit substrate;
a peripheral circuit element disposed on the peripheral circuit substrate; and
a peripheral circuit wiring structure electrically connected to the peripheral circuit element, disposed on the peripheral circuit substrate,
wherein the peripheral circuit wiring structure is disposed on the second side of the cell substrate.

6. The semiconductor memory device of claim 1, further comprising:
a peripheral circuit substrate;
a peripheral circuit element disposed on the peripheral circuit substrate; and
a peripheral circuit wiring structure electrically connected to the peripheral circuit element, disposed on the peripheral circuit substrate,
wherein the peripheral circuit wiring structure is disposed on the first side of the cell substrate.

7. The semiconductor memory device of claim 1,
wherein each of the back gate electrodes of the first and second channel structures comprise a first back gate electrode and a second back gate electrode that are separated from each other.

8. The semiconductor memory device of claim 1, further comprising:
a bit line electrically connected to the first channel structure and the second channel structure,
wherein the first channel structure and the second channel structure are adjacent in the first direction and share the bit line.

9. The semiconductor memory device of claim 1, further comprising:
a bit line that is in contact with the first channel structure and the second channel structure.

10. A semiconductor memory device, comprising:
a cell substrate;
a plurality of gate electrodes sequentially stacked on the cell substrate and extending in a first direction;
first and second channel structures extending in a second direction different from the first direction and penetrating the plurality of gate electrodes; and
a bit line disposed on the plurality of gate electrodes,
wherein the first and second channel structures each include a ferroelectric layer, a channel layer, a gate insulating layer and a back gate electrode, which are sequentially disposed on side walls of the plurality of gate electrodes, and
the first channel structure and the second channel structure are adjacent to each other in the first direction and share a bit line.

11. The semiconductor memory device of claim 10,
wherein a voltage is independently applied to the back gate electrode of the first channel structure and the back gate electrode of the second channel structure.

12. The semiconductor memory device of claim 10,
wherein the plurality of gate electrodes and the first channel structure constitute a plurality of first memory cells,
the plurality of gate electrodes and the second channel structure constitute a plurality of second memory cells, and
a back gate voltage is applied to the back gate electrode of the first channel structure and a ground voltage is applied to the back gate electrode of the second channel structure, at a time of a program operation of a selected memory cell among the plurality of first memory cells.

13. The semiconductor memory device of claim 12,
wherein the plurality of gate electrodes comprises a first gate electrode that forms the selected memory cell, and a plurality of second gate electrodes that do not form the selected memory cell, and
a program voltage is applied to the first gate electrode, and a ground voltage is applied to the plurality of second gate electrodes, at the time of the program operation of the selected memory cell.

14. The semiconductor memory device of claim 10,
wherein the plurality of gate electrodes and the first channel structure constitute a plurality of first memory cells,
the plurality of gate electrodes and the second channel structure constitute a plurality of second memory cells,
a back gate voltage is applied to the back gate electrode of the first channel structure and a ground voltage is applied to the back gate electrode of the second channel structure, at a time of a read operation of a selected memory cell among the plurality of first memory cells.

15. The semiconductor memory device of claim 14,
wherein the plurality of gate electrodes comprises a first gate electrode that forms the selected memory cell, and a plurality of second gate electrodes that do not form the selected memory cell, and
a ground voltage is applied to the first gate electrode, and the plurality of second gate electrodes float, at the time of the read operation of the selected memory cell.

16. The semiconductor memory device of claim 10,
wherein the plurality of gate electrodes, the first channel structure and the second channel structure constitute a plurality of memory cells, and
a back gate voltage is applied to the back gate electrode of the first channel structure and the back gate electrode of the second channel structure, at a time of an erase operation of the plurality of memory cells.

17. The semiconductor memory device of claim 10,
wherein the channel layer of the first channel structure and the channel layer of the second channel structure extend along an upper face of the bit line and are in contact with each other.

18. The semiconductor memory device of claim 10,
wherein the channel layer of the first channel structure and the channel layer of the second channel structure are in contact with a lower face of the bit line.

19. An electronic system, comprising:
a main board;
a semiconductor memory device disposed on the main board; and
a controller electrically connected to the semiconductor memory device, disposed on the main board,
wherein the semiconductor memory device comprises:
a cell substrate;
a plurality of gate electrodes sequentially stacked on the cell substrate and extending in a first direction; and
first and second channel structures extending in a second direction different from the first direction, penetrating through the plurality of gate electrodes, and disposed adjacent to each other,
wherein the first and second channel structures each include a ferroelectric layer, a channel layer, a gate insulating layer and a back gate electrode that are sequentially disposed on side walls of the plurality of gate electrodes, and
a voltage is independently applied to the back gate electrode of the first channel structure and the back gate electrode of the second channel structure.

20. The electronic system of claim 19,
wherein the plurality of gate electrodes and the first channel structure constitute a plurality of first memory cells,
the plurality of gate electrodes and the second channel structure constitute a plurality of second memory cells, and
a back gate voltage is applied to the back gate electrode of the first channel structure and a ground voltage is applied to the back gate electrode of the second channel structure, at a time of a program operation or a read operation of a selected memory cell among the plurality of first memory cells.
